(19) United States
(12) Patent Application Publication
(10) Pub. No.: US 2025/0171689 A1
(43) Pub. Date: May 29, 2025

(54) ETCHING COMPOSITION FOR SILICON NITRIDE LAYER

(71) Applicants: ENF Technology Co., Ltd., Yongin-si (KR); SK hynix Inc., Icheon-si (KR)

(72) Inventors: Dong Hyun KIM, Yongin-si (KR); Hyeon Woo PARK, Yongin-si (KR); Seok Hyeon NAM, Yongin-si (KR); Nam Hee KIM, Yongin-si (KR); Min Young CHO, Yongin-si (KR); Tae Uk OH, Yongin-si (KR); Joo Hwan KIM, Yongin-si (KR); Myung Ho LEE, Yongin-si (KR); Myung Geun SONG, Yongin-si (KR); Eun Seok OH, Icheon-si (KR); Young Mee KANG, Icheon-si (KR)

(21) Appl. No.: 18/959,645

(22) Filed: Nov. 26, 2024

(30) Foreign Application Priority Data
Nov. 27, 2023 (KR) 10-2023-0166416

(51) Int. Cl. C09K 13/06

(52) U.S. Cl. CPC C09K 13/06

(57) ABSTRACT

The present disclosure relates to an etching composition for a silicon nitride layer, and the etching composition for a silicon nitride layer has a significantly excellent etching selectivity for a silicon nitride layer as compared to a silicon oxide layer, prevent abnormal growth of the silicon oxide layer, suppresses particle generation affecting characteristics of a semiconductor device, and has an excellent effect of a significantly small generation height of bubbles.

CROSS-REFERENCE TO RELATED APPLICATION(S)

This application claims benefit of priority to Korean Patent Application No. 10-2023-0166416 filed on Nov. 27, 2023, in the Korean Intellectual Property Office, the disclosure of which is incorporated herein by reference in its entirety.

### BACKGROUND

### 1. Field

The present disclosure relates to an etching composition for a silicon nitride layer, and relates to a composition that may selectively etch a silicon nitride layer as compared to a silicon oxide layer and a method of manufacturing a semiconductor device including a process performed using the composition.

### 2. Description of Related Art

A silicon oxide (SiO₂) film and a silicon nitride (SiNₓ) layer are representative insulating layers used in semiconductor manufacturing processes. Such layers are used alone or in the form in which one or more layers of silicon oxide and one or more layers of silicon nitride are alternately stacked. Additionally, the silicon oxide layer and the silicon nitride layer are also used as hard masks for forming conductive patterns such as metal wiring.

In conventional semiconductor manufacturing processes, phosphoric acid is used to remove silicon nitride layers, but phosphoric acid may be changed to pyrophosphoric acid or various forms of polyacids at high temperatures, or may affect an etching ratio of a nitride layer and an oxide layer by autoprotolysis, so that deionized water should be supplied. However, even a slight change in the amount of deionized water supplied may cause defects during the removal of silicon nitride layers, and phosphoric acid itself may be a strong acid and corrosive, it is not easy to handle the deionized water and phosphoric. Additionally, the silicon nitride layer reacts with phosphoric acid and changes into the form of H₂SiO₃, but some of the silicon nitride layers are dissociated and exist in the solution in the form of silicon ions, and there may be an abnormal growth problem in which the concentration of silicon ions in an etching composition increases due to Le Chatelier's principle to increase a thickness of the silicon oxide layer.

Various studies have been conducted to solve these problems, and these studies may be largely classified into three types.

First is a technology to increase an etching rate of the silicon nitride layer. Specifically, an etching method has been proposed to heat phosphoric acid to obtain polyphosphoric acid and then etch polyphosphoric acid at 100° C. or higher to increase the selectivity. However, the method has not verified an effect of improving the selectivity according to the stability and crystal structure of polyphosphoric acid, and may make it difficult to quantify the concentration of polyphosphoric acid and may make it difficult to control a process temperature due to excessive heat generation during hydration. Additionally, since the etching ratio of the silicon oxide layer also increases, it may difficult to apply the method to a micro process, which is not desirable.

Second is a technology to reduce an etching rate of the silicon oxide layer. Specifically, an etching solution that may selectively etch silicon nitride layers by adding sulfuric acid, an oxidizer, or the like, to phosphoric acid, has been proposed. However, when sulfuric acid is added thereto, it may be difficult to improve a desired selectivity and the production efficiency decreases because the etching rate of not only the silicon oxide layer but also the silicon nitride layer decreases, which is not desirable.

Third is a technology to add a fluorine-based compound. Specifically, an etching method has been proposed to improve the selectivity for the silicon nitride layer by adding a small amount of nitric acid and hydrofluoric acid to phosphoric acid. However, the method has a problem in that the etching rate of the silicon oxide layer also increases due to the addition of hydrofluoric acid. Additionally, an etching solution that may selectively etch the silicon nitride layers by adding a silicon-based fluoride has been proposed, but the method has problems such as a very short lifespan of the etching solution and poor compatibility with additives.

As described above, various methods have been used to improve the etching rate and selectivity of the silicon nitride layers, but all of the methods may cause particles on a wafer surface as the processing time increases, which is not desirable for long-term use thereof.

Specifically, when an etching composition is repeatedly reused for an etching treatment or the processing time increases, a fatal problem occurs that affects the silicon oxide layer and causes abnormal growth of the silicon oxide layer. Furthermore, in order to manufacture semiconductor devices of a certain quality, the generation of bubbles should be minimized to ensure process stability, but when additives are introduced, the etching selectivity or the etching ratio may be secured, but the process stability deteriorates due to the generation of excessive bubbles, which may cause a problem of deterioration in the quality of the semiconductor device.

Accordingly, the development of a silicon nitride layer etching solution having a new composition, which may overcome the above-described problems, is required.

### PRIOR ART REFERENCE

### Patent Document

(Patent literature 1): KR 10-2457243 B1 (Oct. 17, 2022)

### SUMMARY

An aspect of the present disclosure is to provide an etching composition for a silicon nitride layer that may etch a silicon nitride layer at a high etching selectivity as compared to a silicon oxide layer.

Additionally, another aspect of the present disclosure is to provide an etching composition for a silicon nitride layer that may prevent or minimize the occurrence of abnormal growth in a silicon oxide layer.

Additionally, another aspect of the present disclosure is to provide an etching composition for a silicon nitride layer that may minimize damage to other films around a silicon oxide layer, including the silicon oxide layer, and may suppress the occurrence of particles affecting characteristics of a semiconductor device, in the semiconductor manufacturing process, and may manufacture a semiconductor device having a constant quality by minimizing the generation of bubbles to maintain process stability.

An etching composition for a silicon nitride layer according to the present disclosure includes phosphoric acid, a silicon-based compound represented by Formula 1, and water.

(R₁R₂R₃)Si—O—Si(R₄R₅R₆) [Formula 1]

R₁ may be *-L₁-[N (R₇)-L₂]ₙ-N(R₈R₉), R₄ may be selected from (C1-C7)alkyl, hydroxy (C1-C7)alkyl, (C1-C7)alkylamino, hydroxy (C1-C7)alkylamino, (C1-C7)alkoxy, hydroxy (C1-C7)alkoxy, and chloro (C1-C7)alkyl, R₂, R₃, R₅ and R₆ may be each independently selected from halogen, hydroxy, (C1-C7)alkyl, (C1-C7)alkoxy, (C1-C7)alkylamino, chloro (C1-C7)alkyl, and *-O—P(═O)(OR₁₀) (OR₁₁), L₁ and L₂ may be each independently (C1-C10)alkylene, R₇ to R₁₁ may be each independently hydrogen or (C1-C7)alkyl, n may be an integer from 0 to 10, and at least one —CH₂— of (C1-C10)alkylene of L₁ and L₂ may be substituted with —O—, —OC(═O)—, —NHC(═O)—, —NHC(═O)O—, —C(═O)— or —OC(═O)O—.

According to an embodiment, in Formula 1, R₄ may be selected from hydroxy(C1-C7)alkyl, hydroxy(C1-C7)alkoxy, and hydroxy(C1-C7)alkylamino.

According to an embodiment, in Formula 1, R₄ may be hydroxy (C1-C7) alkyl.

According to an embodiment, in Formula 1, R₂, R₃, R₅ and R₆ may be each independently selected from hydroxy, (C1-C7)alkyl, (C1-C7)alkoxy, and *-O—P(═O)(OR₁₀)(OR₁₁).

According to an embodiment, in Formula 1, R₂, R₃, R₅ and R₆ may be each independently selected from hydroxy, (C1-C4)alkoxy, and *-O—P(═O)(OR₁₀)(OR₁₁).

According to an embodiment, in Formula 1, L₁ and L₂ may be each independently be (C1-C4)alkylene, R₇ to R₉ are each independently hydrogen or (C1-C4)alkyl, and n is an integer of 0 to 5.

According to an embodiment, in Formula 1, L₁ and L₂ may be each independently (C1-C4)alkylene, R₇ to R₉ are hydrogen, and n is an integer from 0 to 3.

According to an embodiment, a compound represented by formula 1 may be selected from the following compounds.

(OH)₂(R₁ₐ)Si—O—Si(R₄ₐ)(OH)₂ [Formula 2]

(—O—P(═O)(OH)₂)₂(R₁ₐ)Si—O—Si(R₄ₐ)(—O—P(═O)(OH)₂)₂ [Formula 3]

(OH)(R₁ₐ)(R₂ₐ)Si—O—Si(R₄ₐ)(OH)₂ [Formula 4]

(—O—P(═O)(OH)₂)(R₁ₐ)(R₂ₐ)Si—O—Si(R₄ₐ)(—O—P(═O)(OH)₂)₂ [Formula 5]

R₁ₐ is *-(CH₂)ₘ—NH₂ or *-(CH₂)₃—[NH—(CH₂)₂]—NH₂, R₂ₐ is methyl or ethyl, R₄ₐ is hydroxy(C1-C2)alkyl or chloro(C1-C2)alkyl, and m is an integer of 2 to 4.

According to another embodiment, a compound represented by Formula 1 may be selected from the following compounds.

(OH)₂(R_{1b})Si—O—Si(R_{4b})(OH)₂ [Formula 6]

(—O—P(═O)(OH)₂)₂(R_{1b})Si—O—Si(R_{4b})(—O—P(═O)(OH)₂)₂ [Formula 7]

(OH)(R_{1b})(R_{2b})Si—O—Si(R_{4b})(OH)₂ [Formula 8]

(—O—P(═O)(OH)₂)(R_{1b})(R_{2b})Si—O—Si(R_{4b})(—O—P(═O)(OH)₂)₂ [Formula 9]

R_{1b} is *-(CH₂)ₘ—NH₂ or *-(CH₂)₃—[NH—(CH₂)₂]—NH₂, R_{2b} is methyl or ethyl, and R₄b is (C1-C2)alkyl.

According to an embodiment, the etching composition may include 80 to 90 wt % of phosphoric acid, 0.01 to 10 wt % of a silicon-based compound represented by Formula 1, and a residual amount of water.

According to an embodiment, the etching composition for a silicon nitride layer may further include: one or two or more combinations selected from the group consisting of pyrophosphoric acid, polyphosphoric acid, phosphorous acid, dialkyl phosphite, sulfuric acid, alkylsulfonic acid, hydrochloric acid, hydrofluoric acid, and derivatives thereof.

According to an embodiment, the etching composition for a silicon nitride layer may further include an ammonium-based compound.

According to an embodiment, etching selectivity of the following relational expression 1 may be satisfied.

500≤E_{SiNx}/E_{SiO2} [Relational Expression 1]

E_{SiNx} is an etching rate of the silicon nitride layer, and E_{SiO2} is an etching rate of the silicon oxide layer.

A method of manufacturing a semiconductor device according to the present disclosure may include an etching process using the composition for etching a silicon nitride layer described above.

An etching composition for a silicon nitride layer according to the present disclosure may etch the silicon nitride layer at a higher etching selectivity than the silicon oxide layer, and may prevent or minimize the occurrence of abnormal growth in the silicon oxide layer.

Additionally, an etching composition for a silicon nitride layer may minimize damage to other films around a silicon oxide layer, including the silicon oxide layer, and may suppress the occurrence of particles affecting characteristics of a semiconductor device, and may manufacture a semiconductor device having a constant quality by minimizing the generation of bubbles to maintain process stability.

### DETAILED DESCRIPTION

In the technical and scientific terms used in the present specification, unless otherwise defined, the terms have the meanings commonly understood by those of ordinary skill in the art to which this invention belongs, and descriptions of well-known functions and configurations that may unnecessarily obscure the gist of the present disclosure in the following description and accompanying drawings will be omitted.

Additionally, the singular form used in the present specification may be intended to include a plural form as well, unless specifically indicated in the context.

Additionally, units used in the present specification without special mention are based on weight, and for example, the unit of % or ratio refers to mass % or mass ratio, and mass % refers to the mass % that any one component of the total composition occupies in the composition, unless otherwise defined.

Additionally, a numerical range used in the present specification includes a lower limit and an upper limit and all values within that range, an increment logically derived from a shape and a width of the defined range, and all possible combinations of double-limited values and the upper limit and the lower limit of a numerical range limited in different forms. Unless otherwise specifically defined in the present specification, values outside the numerical range that may occur due to experimental error or rounding of values are also included in the defined numerical range.

The term “includes” in the present specification is an open-type description equivalent to expressions such as “comprise,” “contains,” “has,” or “characterizes,” and does not exclude additional elements, materials, or processes that are not listed.

An etching composition for a silicon nitride layer

according to the present disclosure includes phosphoric acid, a silicon-based compound represented by Formula 1, and water.

(R₁R₂R₃)Si—O—Si(R₄R₅R₆) [Formula 1]

R₁ may be *-L₁-[N(R₇)-L₂]ₙ-N(R₈R₉), R₄ may be selected from (C1-C7)alkyl, hydroxy (C1-C7)alkyl, (C1-C7)alkylamino, hydroxy (C1-C7)alkylamino, (C1-C7)alkoxy, hydroxy (C1-C7)alkoxy, and chloro (C1-C7)alkyl, R₂, R₃, R₅ and R₆ may be each independently selected from halogen, hydroxy, (C1-C7)alkyl, (C1-C7)alkoxy, (C1-C7)alkylamino, chloro (C1-C7)alkyl, and *-O—P(═O)(OR₁₀) (OR₁₁), L₁ and L₂ may be each independently (C1-C10)alkylene, R₇ to R₁₁ may be each independently hydrogen or (C1-C7)alkyl, n may be an integer from 0 to 10, and at least one —CH₂— of (C1-C10)alkylene of L₁ and L₂ may be substituted with —O—, —OC(═O)—, —NHC(═O)—, —NHC(═O)O—, —C(═O)—or —OC(═O)O—.

An etching composition for a silicon nitride layer according to the present disclosure may etch a silicon nitride layer with a high etching selectivity as compared to a silicon oxide layer. Additionally, the etching composition may prevent or minimize abnormal growth of a silicon oxide layer, may minimize damage to other films existing around the silicon oxide layer, including the silicon oxide layer, and may suppress an occurrence of particles affecting the characteristics of a semiconductor device.

A silicon compound represented by formula 1 is a disiloxane compound, and includes two different Si atoms bonded with three substituents, but the three substituents bonded to each Si atom are not all the same, and one Si atom includes a nucleophile represented by *-L₁-[N(R₇)-L₂]ₙ-N (R₈R₉).

The phosphoric acid is a main etching material, and provides hydrogen ions in the composition, thus serving to further promote the etching of a silicon nitride layer.

The water is not particularly limited, but is preferably deionized water, and more preferably, the water is deionized water for a semiconductor process, and may have a resistivity value of 18 MΩ·cm or more. However, this is only a preferred example, and the present disclosure is not limited thereto.

According to an embodiment, in Formula 1, R₄ may be selected from hydroxy(C1˜C7)alkyl, hydroxy(C1˜C7)alkoxy, and hydroxy(C1˜C7)alkylamino. The R₄ substituent may suppress abnormal growth of the silicon oxide layer by including a hydroxy terminal interposed by an alkylene group.

Specifically, R₄ may be selected from hydroxy(C1˜C4)alkyl, hydroxy(C1˜C4)alkoxy and hydroxy(C1˜C4)alkylamino, and more specifically, R₄ may be selected from hydroxy(C1˜C3)alkyl, hydroxy(C1˜C3)alkoxy and hydroxy(C1˜C3)alkylamino.

According to an embodiment, in Formula 1, R₄ may be hydroxy(C1˜C7)alkyl. Specifically, R₄ may be hydroxy(C1˜C4)alkyl, and more specifically, R₄ may be hydroxy(C1˜C3)alkyl or hydroxy(C1˜C2)alkyl. More specifically, R₄ may be hydroxymethyl or hydroxyethyl, and hydroxymethyl may be selected without limitation. Since R₄ has the substituent as described above, the generation of bubbles in an etching solution may be minimized to ensure excellent process stability, and may significantly suppress abnormal growth of the silicon oxide layer.

According to another embodiment, in Formula 1, R₄ may be selected from (C1˜C7) alkyl, (C1˜C7) alkylamino, and chloro(C1˜C7) alkyl. Specifically, R₄ may be selected from (C1˜C4) alkyl, (C1˜C4) alkylamino, and chloro(C1˜C4) alkyl, and more specifically, R₄ may be (C1˜C4) alkyl or chloro(C1˜C4) alkyl. More specifically, R₄ may be methyl, ethyl, chloromethyl, or chloroethyl.

R₂, R₃, R₅ and R₆ may be each independently selected from halogen, hydroxy, (C1-C4)alkyl, (C1-C4)alkoxy, (C1-C4)alkylamino, chloro(C1˜C4)alkyl and *-O—P(═O)(OR₁₀)(OR₁₁), and R₁₀ to R₁₁ may be each independently hydrogen or (C1˜C4)alkyl. The halogen may be selected from F, Cl, Br, I, and the like.

According to an embodiment, in Formula 1, R₂, R₃, R₅ and R₆ may be each independently selected from hydroxy, (C1-C7)alkyl, (C1-C7)alkoxy and *-O—P(═O)(OR₁₀)(OR₁₁), R₁₀ to R₁₁ may be each independently hydrogen or (C1˜C4)alkyl. While R₂, R₃, R₅ and R₆ have the substituents as described above, R₄ may be selected from hydroxy(C1˜C7)alkyl, hydroxy(C1˜C7)alkoxy and hydroxy(C1˜C7)alkylamino, and more specifically, R₄ may be hydroxy(C1˜C7)alkyl, hydroxy(C1˜C4)alkyl, hydroxy(C1˜C3)alkyl, or hydroxy(C1˜C2)alkyl. More specifically, R₂, R₃, R₅ and R₆ may be each independently selected from hydroxy, (C1-C4)alkyl, (C1-C4)alkoxy and *-O—P(═O)(OR₁₀)(OR₁₁), and may be preferably combined with the R₄ substituents as described above.

According to a preferred embodiment, in Formula 1, R₂, R₃, R₅ and R₆ may be each independently selected from hydroxy, (C1-C4)alkoxy and *-O—P(═O)(OR₁₀)(OR₁₁), and R₁₀ to R₁₁ may be each independently hydrogen or (C1˜C4)alkyl, specifically hydrogen. While R₂, R₃, R₅ and R₆ have the substituents as described above, R₄ may be selected from hydroxy(C1˜C7)alkyl, hydroxy(C1˜C7)alkoxy and hydroxy(C1˜C7)alkylamino, and more specifically, R₄ may be hydroxy(C1˜C7)alkyl, hydroxy(C1˜C4)alkyl, hydroxy(C1˜C3)alkyl, or hydroxy(C1˜C2)alkyl. Specifically, R₂, R₃, R₅ and R₆ may be each independently selected from hydroxy and *-O—P(═O)(OR₁₀)(OR₁₁) and may be preferably combined with the R₄ substituent as described above.

According to an embodiment, in Formula 1, R₆ and R₂, R₃ and R₅ may have different substituents. Since Re and the remaining substituents R₂, R₃ and R₅ have different substituents, the etching composition for a silicon nitride layer may etch a silicon nitride layer with a high etching selectivity as compared to a silicon oxide layer.

Specifically, L₁ and L₂ may each independently be linear or branched (C1-C7)alkylene or linear or branched (C1-C4)alkylene. Additionally, R₇ to R₁₁ may each independently be hydrogen or (C1˜C4)alkyl, and n may be an integer from 0 to 8, or from 0 to 5.

According to an embodiment, L₁ and L₂ may each independently be a straight chain or branched chain (C1-C4) alkylene, R₇ to R₉ may each independently be hydrogen or (C1˜C4) alkyl, and n may be an integer from 0 to 5. Specifically, L₁ and L₂ may each independently be a straight chain or branched chain (C1-C4) alkylene, R₇ to R₉ may each independently be hydrogen, methyl or ethyl, and n may be an integer from 0 to 3.

According to an embodiment, L₁ and L₂ may each independently be a straight chain or branched chain (C1-C4) alkylene, R₇ to R₉ may be hydrogen, and n may be an integer from 0 to 3. Specifically, L₁ may be a straight chain or branched chain (C1-C4) alkylene, L₂ may be ethylene, R₈ to R₉ may be hydrogen, and n may be an integer from 0 to 3. For example, R₁ may be *-(CH₂)ₘ—[NH—(CH₂)₂]ₙ—NH₂, where m may be an integer from 1 to 4, and n may be an integer from 0 to 3. Specifically, *-(CH₂)₂—NH₂, *-(CH₂)₃—NH₂, *-(CH₂)₄—NH₂, *-(CH₂)₂—[NH—(CH₂)₂]—NH₂, *-(CH₂)₃—[NH—(CH₂)₂]—NH₂, *-(CH₂)₃—[NH—(CH₂)₂]₂—NH₂ or *-(CH₂)₃—[NH—(CH₂)₂]₃—NH₂ may be exemplified, but the present disclosure is not limited thereto.

According to an embodiment, a compound represented by formula 1 may be selected from the following compounds.

(OH)₂(R₁ₐ)Si—O—Si(R₄ₐ)(OH)₂ [Formula 2]

(—O—P(═O)(OH)₂)₂(R₁ₐ)Si—O—Si(R₄ₐ)(—O—P(═O)(OH)₂)₂ [Formula 3]

(OH)(R₁ₐ)(R₂ₐ)Si—O—Si(R₄ₐ)(OH)₂ [Formula 4]

(—O—P(═O)(OH)₂)(R₁ₐ)(R₂ₐ)Si—O—Si(R₄ₐ)(—O—P(═O)(OH)₂)₂ [Formula 5]

In Formulas 2 to 5, R₁ₐ is *-(CH₂)ₘ—NH₂ or *-(CH₂)₃—[NH—(CH₂)₂]—NH₂, R₂ₐ is methyl or ethyl, R₄ₐ is hydroxy(C1-C2)alkyl or chloro(C1-C2)alkyl, and m is an integer of 2 to 4.

Specifically, in Formulas 2 and 3, Ria may be *-(CH₂)ₘ—NH₂ or *-(CH₂)₃—[NH—(CH₂)₂]-NH₂, R₄ₐ may be hydroxy(C1˜C2)alkyl or chloro(C1˜C2)alkyl, and m may be an integer of 2 to 4. For example, provided may be a compound in which R₁ₐ is *-(CH₂)₃—NH₂ and R₁ₐ is hydroxymethyl, a compound in which R₁ₐ is *-(CH₂)₃—[NH—(CH₂)₂]—NH₂ and R₁ₐ is hydroxyethyl, a compound in which R₁ₐ is *-(CH₂)₃—[NH—(CH₂)₂]—NH₂ and Rea is hydroxymethyl, a compound in which R₁ₐ is *-(CH₂)₃—NH₂ and R₄a is hydroxyethyl, a compound in which R₁ₐ is *-(CH₂)₃—NH₂ and R₄a is chloromethyl, a compound in which Ria is *-(CH₂)₃—NH₂ and R₄a is chloroethyl, a compound in which R₁ₐ is *-(CH₂)₃—[NH—(CH₂)₂]—NH₂ and R₁ₐ is chloromethyl, and a compound in which R₁ₐ is *-(CH₂)₃—[NH—(CH₂)₂]—NH₂ and R₄ₐ is chloroethyl.

Additionally, in Formulas 4 and 5, R₁ₐ may be *-(CH₂)ₘ—NH₂ or *-(CH₂)₃—[NH—(CH₂)₂]—NH₂, R₂ₐ may be methyl or ethyl, R₄ₐ may be hydroxy(C1˜C2)alkyl or chloro(C1˜C2)alkyl, and m may be an integer of 2 to 4. For example, provided may be a compound in which R₁ₐ is *-(CH₂)₃—NH₂, R₂ₐ is methyl and Rea is hydroxymethyl, a compound in which R₁ₐ is *-(CH₂)₃—NH₂, R₂ₐ is methyl and R₄ₐ is hydroxyethyl, a compound in which R₁ₐ is *-(CH₂)₃—[NH—(CH₂)₂]—NH₂, R₂ₐ is methyl and R₄ₐ is hydroxymethyl, a compound in which R₁ₐ is *-(CH₂)₃—[NH—(CH₂)₂]—NH₂, R₂ₐ is methyl and R₄ₐ is hydroxyethyl, a compound in which R₁ₐ is *-(CH₂)₃—NH₂, R₂ₐ is methyl and R₄ₐ is chloromethyl, a compound in which R₁ₐ is *-(CH₂)₃—NH₂, R₂ₐ is methyl and R₁ₐ is chloroethyl, a compound in which R₁ₐ is *-(CH₂)₃—[NH—(CH₂)₂]—NH₂, R₂ₐ is methyl, R₄ₐ is chloromethyl, and a compound in which R₁ₐ is *-(CH₂)₃—[NH—(CH₂)₂]—NH₂, R₂ₐ is methyl and R₄ₐ is chloroethyl.

According to another embodiment, a compound

represented by formula 1 may be selected from the following compounds.

(OH)₂(R_{1b})Si—O—Si(R_{4b})(OH)₂ [Formula 6]

(—O—P(═O)(OH)₂)₂(R_{1b})Si—O—Si(R_{4b})(—O—P(═O)(OH)₂)₂ [Formula 7]

(OH)(R_{1b})(R_{2b})Si—O—Si(R_{4b})(OH)₂ [Formula 8]

(—O—P(═O)(OH)₂)(R_{1b})(R_{2b})Si—O—Si(R_{4b})(—O—P(═O)(OH)₂)₂ [Formula 9]

In Formulas 6 and 7, R_{1b} may be *-(CH₂)ₘ—NH₂ or *-(CH₂)₃—[NH—(CH₂)₂]—NH₂, and R_{4b} may be (C1˜C2)alkyl. Specifically, provided may be a compound in which R_{1b} is *-(CH₂)₃—NH₂ and R_{4b} is methyl, and a compound in which R_{1b} is *-(CH₂)₃—[NH—(CH₂)₂]—NH₂ and R_{4b} is methyl.

Additionally, in Formulas 8 and 9, R_{1b} may be *-(CH₂)ₘ—NH₂ or *-(CH₂)₃—[NH—(CH₂)₂]—NH₂, R_{2b} may be methyl or ethyl, and R_{4b} may be (C1˜C2)alkyl. Specifically, provided may be a compound in which R_{1b} is *-(CH₂)₃—NH₂ and R_{2b} and R_{4b} are methyl, and a compound in which R_{1b} is *-(CH₂)₃—[NH—(CH₂)₂]—NH₂ and R_{2b} and R_{4b} are methyl.

According to an embodiment, the etching composition for a silicon nitride layer may include 60 to 98 mass % of phosphoric acid, 0.001 to 20 mass % of a compound represented by Formula 1 and a residual amount of water, or 70 to 95 mass % of phosphoric acid, 0.01 to 15 mass % of a compound represented by Formula 1 and a residual amount of water, or 80 to 90 mass % of phosphoric acid, 0.01 and 10 mass % of a silicon-based compound represented by Formula 1 and a residual amount of water. When this condition is satisfied, not only may particle generation be effectively suppressed, but also a silicon nitride layer may be etched with high etching selectivity with excellent stability even during a high-temperature semiconductor etching process. Water may be added so that the total mass becomes 100 mass % excluding phosphoric acid and the compound represented by the chemical formula 1, and when other additives are added, water may be added so that the total mass becomes 100 mass % including the content to which the additives are added.

According embodiment, the etching to an composition for a silicon nitride layer may further include one or two or more combinations of acid additives selected from the group consisting of pyrophosphoric acid, polyphosphoric acid, phosphorous acid, dialkyl phosphite, sulfuric acid, alkyl sulfonic acid, hydrochloric acid, hydrofluoric acid, and derivatives thereof. The derivatives of the acid additives may include, for example, derivatives substituted with (C1-C7) alkyl, derivatives substituted with alkali metal salts ammonium salts, or derivative structures known in the art, but the present disclosure is but not limited thereto.

The content of the acid additive is not particularly limited, and for example, the acid additive may be used in an amount of 0.01 to 3 mass % with respect to an entire composition. However, this is only a preferred example, and the present disclosure is not limited thereto.

According to an embodiment, the etching composition for a silicon nitride layer may further include an ammonium-based compound. The ammonium-based compound may include, for example, ammonium phosphate, ammonium sulfate, ammonium chloride, ammonium hydroxide, ammonium fluoride, ammonium acetate, tetramethylammonium hydroxide, tetraethylammonium hydroxide, tetrapropylammonium hydroxide, tetrabutylammonium hydroxide, tetramethylammonium chloride, tetramethylammonium phosphate, tetramethylammonium sulfate, tetramethylammonium fluoride, choline, but the present disclosure is not limited thereto.

As the ammonium-based compound is further included, provided may be a stable etching composition for a silicon nitride layer that does not cause particle problems even during long-term processing, and that may more stably maintain an etching rate and etching selectivity for the silicon nitride layer and may minimize a defect rate occurring during the etching of a semiconductor device. The content of the above ammonium compound is not significantly limited, and for example, the ammonium compound may be used at 0.01 to 3 mass % for the entire composition. However, this is only a preferred example, and the present disclosure is not limited thereto.

According to an embodiment, an etching composition for a silicon nitride layer may satisfy the etching selectivity (E_{SiNx}/E_{SiO2}) of the following relational expression 1, specifically the etching selectivity (E_{SiNx}/E_{SiO2}) of the following relational expression 2, more specifically the etching selectivity (E_{SiNx}/E_{SiO2}) of the following relational expression 3, even more specifically the etching selectivity (E_{SiNx}/E_{SiO2}) of the following relational expression 4, or the etching selectivity (E_{SiNx}/E_{SiO2}) of the following relational expression 5, but the present disclosure is not limited to the numerical range described above. In this case, in the following relational expression 1 to 5, E_{SiNx}is an etching rate of the silicon nitride layer, and E_{SiO2} is the etching rate of the silicon oxide layer.

500≤E_{SiNx}/E_{SiO2} [Relational Expression 1]

500≤E_{SiNx}/E_{SiO2}≤2,500 [Relational Expression 2]

800≤E_{SiNx}/E_{SiO2}≤2,500 [Relational Expression 3]

1,000≤E_{SiNx}/E_{SiO2}≤2,500 [Relational Expression 4]

1,400≤E_{SiNx}/E_{SiO2}≤2,400 [Relational Expression 5]

The ‘etching selectivity (E_{SiNx}/E_{SiO2})’ described in this specification refers to a ratio of an etching rate (E_{SiNx}) of the silicon nitride layer to an etching rate (E_{SiO2}) of the silicon oxide layer. Additionally, when the etching rate of the silicon oxide layer is almost close to 0 or a value of the etching selectivity is large, the silicon nitride layer may be etched more selectively.

The etching composition for a silicon nitride layer according to an embodiment may have an etching rate for the silicon nitride layer of 20 A/min or more, or 20 to 100 A/min, and specifically, the etching rate may be 40 to 80 A/min, but the present disclosure is not limited thereto.

In an etching composition for a silicon nitride layer according to an embodiment, when a silicon nitride layer and a silicon oxide layer are mixed, only the silicon nitride layer may be selectively etched with a very high selectivity without substantially affecting an etching effect on the silicon oxide layer, and defect problems may be minimized in manufacturing a semiconductor device by not causing particles on a substrate surface.

Additionally, the etching composition for the silicon nitride layer according to an embodiment has high temperature stability to effectively suppress the problem in which phosphoric acid heated to a high temperature etches the silicon oxide layer, so that the etching composition for the silicon nitride layer may prevent substrate defects by not generating foreign substances, and may selectively etch the silicon to implement excellent nitride layer semiconductor device characteristics. Additionally, the etching composition for the silicon nitride layer does not substantially affect the silicon oxide layer in an etching process, and may prevent or minimize abnormal growth of the silicon oxide layer.

The present disclosure also provides a method of selectively etching a silicon nitride layer as compared to a silicon oxide layer using the etching composition of the silicon nitride layer as described above. In this case, the etching method may be performed according to a method commonly used in the art, which may be performed according to a method known in the art, and examples thereof may include an etching method by immersion, and an etching method by spraying. Specifically, the method may include an operation of selectively etching the silicon nitride layer by allowing a substrate on which the silicon oxide layer and the silicon nitride layer are stacked to contact the etching composition for the silicon nitride layer as described above; and an operation of cleaning the etched substrate.

Additionally, according to the etching method according to the present disclosure, particle problems may not be caused even when performing repetitive etching processes, thereby enabling more stable etching. Additionally, the silicon nitride layer may be selectively etched with a significantly high selectivity, thereby effectively preventing the silicon oxide layer from being removed or damaged unnecessarily or excessively.

According to an embodiment, the etching composition for the silicon nitride layer may be preferably performed at a high temperature during the etching process, and specifically, a process temperature may be 50 to 300° C., preferably 100 to 200° C., but an appropriate temperature may be changed as needed in consideration of other processes and other factors. Accordingly, the etching composition for the silicon nitride layer may be efficiently used in various processes requiring selective etching of the silicon nitride layer with respect to the silicon oxide layer in each etching process.

The present disclosure also provides a method of manufacturing a semiconductor device including an etching process using the etching composition silicon nitride layer as described above. Specifically, according to the method of manufacturing a semiconductor device including an etching process performed using the etching composition for the silicon nitride layer according to the present disclosure, when the silicon nitride layer and the silicon oxide layer are alternately stacked or mixed, selective etching of the silicon nitride layer may be performed. Additionally, particle generation, which was a problem in the conventional etching process, may be prevented, thereby ensuring stability and reliability of the process. In this case, the type of semiconductor devices is not specifically limited in the present disclosure.

The substrate may be formed of various materials, for example, silicon, quartz, glass, silicon wafers, polymers, metals, and metal oxides, but the materials are not limited thereto. As an example of the polymer substrate, a film substrate such as polyethylene terephthalate, polycarbonate, polyimide, polyethylene naphthalate, cycloolefin polymer, or the like, may be used, but the present disclosure is not limited thereto.

The ‘silicon nitride layer’ described in this specification may be various silicon-based nitride layers such as a SiN layer, a SiON layer, a doped SiN layer, or the like, which is a concept including such silicon-based nitride layers, and as a specific example, the ‘silicon nitride layer’ may refer to a film membrane mainly used as an insulating film when forming a gate electrode, or the like. However, the silicon-based nitride layers may be used without limitation in any technical field that has the purpose of selectively etching silicon nitride layers over silicon oxide layers.

Additionally, the ‘silicon oxide layer’ described in this specification is not limited as long as this is a silicon oxide layer commonly used in the art, and for example, the ‘silicon oxide layer’ may be at least one film selected from the group consisting of: a Spin On Dielectric (SOD) film, an High Density Plasma (HDP) film, a thermal oxide layer, a Borophosphate Silicate Glass (BPSG) film, a Phospho

Silicate Glass (PSG) film, a Boro Silicate Glass (BSG) film, a Polysilazane (PSZ) film, a Fluorinated Silicate Glass (FSG) film, a Low Pressure Tetra Ethyl Ortho Silicate (LP-TEOS) film, a Plasma Enhanced Tetra Ethyl Ortho Silicate (PETEOS) film, a High Temperature Oxide (HTO) film, a Medium Temperature Oxide (MTO) film, a Undoped Silicate Glass (USG) film, a Spin On Glass (SOG) film, an Advanced Planarization Layer (APL), an Atomic Layer Deposition (ALD) film, a Plasma Enhanced oxide (PE-oxide layer) film, a O3-Tetra Ethyl Ortho Silicate (O3-TEOS) film, and combinations thereof. However, this is only a specific example and the present disclosure is not limited thereto.

As described above, the present disclosure has been described in detail through each aspect and embodiment of the present disclosure, and each embodiment described in the specification does not mean only one embodiment but also means a combination with other embodiments. Accordingly, the citation of the claims in the scope of the patent claims is only one example and the technical idea of the present disclosure should not be interpreted only as a combination with the cited claims, and includes and various combinations with the claims are also included in the scope of the technical idea of the present disclosure.

Hereinafter, the present disclosure will be described in more detail using embodiments, but the following examples are only examples to help understanding of the present disclosure, and the technical idea of the present disclosure is not limited to the following examples. Accordingly, the technical idea of the present disclosure should not be limited to the described embodiments, and all things that are equivalent or equivalent to the scope of the patent claims described below, as well as the patent claims, are considered to fall within the scope of the technical idea of the present disclosure.

### Evaluation Method

### (1) Measurement of Etching Rate

A silicon nitride wafer and a silicon oxide wafer were prepared by depositing in the same manner as the semiconductor manufacturing process using a chemical vapor deposition method. An LP Nitride (with a thickness of 5, 000 Å) layer was used as the silicon nitride wafer, and a PE-TEOS (with a thickness 500 Å) film was used as the silicon oxide wafer.

A thickness of a composition before etching was

measured using an ellipsometer (J.A WOOLLAM, M-2000U), a thin film thickness measuring device. The wafer was immersed in each of the compositions of the following inventive examples and comparative examples maintained at an etching temperature of 160 to 230° C. in a quartz bath for 30 minutes, and an etching process was performed. After the etching was completed, the wafer was washed with ultrapure water, and the remaining etchant and moisture were completely dried using a drying device, and an etching rate was measured.

The etching rate was calculated by dividing a difference between the thickness before and after etching by the etching time (minutes) using the ellipsometer, and the etching selectivity calculated therefrom was recorded in Table 2 below.

### (2) Measurement of Abnormal Growth Occurrence Level (Å) of Silicon Oxide Layer

An abnormal growth occurrence level of the silicon oxide layer was measured according to the concentration of etching byproducts generated by accumulating the silicon nitride layer. The difference between the thickness of the composition before and after etching was measured using an ellipsometer (J.A WOOLLAM, M-2000U), a film thickness measuring device. IN this case, when the thickness of the film increased after etching, abnormal growth was determined to occur, and quantitative values thereof were recorded in Table 3 below.

### (3) Measurement of Precipitate Occurrence

By utilizing the compositions of the following inventive examples and comparative examples, a surface of the silicon oxide layer etched was photographed at 100, 000× magnification at five random positions using a scanning electron microscope (SEM), and the occurrence of precipitates (O: occurrence/X: non-occurrence) was examined and recorded in Table 3 below.

### (4) Bubble Generation Height

60 ml of the composition was placed in a 250 ml mass cylinder, and nitrogen gas was inserted at a rate of 5 L/min for 20 seconds using a microbubbler. After 20 seconds, a height of bubbles generated in the mass cylinder was measured.

### Inventive Examples 1 to 6 and Comparative Examples 1 to 3

After performing mixing in composition ratios described in Table 1 below, the compositions were stirred at a rate of 300 rpm for 5 minutes at room temperature to prepare an etching composition for a silicon nitride layer. A water content was the remaining amount so that the total weight of the composition was 100 wt %, and 300 g of an etching composition for a silicon nitride layer was prepared.

After the preparation of the silicon nitride layer etching composition was completed, a substrate on which the silicon nitride layer and the silicon oxide layer were deposited was immersed in the etching composition for a silicon nitride layer to perform an etching process of the substrate. A temperature of the etching composition for a silicon nitride layer was as described in Table 1, and the immersion time was identically maintained at 20 minutes. After the immersion was completed, repeated washing was performed with distilled water, and the etching characteristics were evaluated according to the evaluation method described above.

TABLE 1

| | Phosphoric | | | | |
|---|---|---|---|---|---|
| | acid | Formula 1 | | | Evaluation |
| | Content | | Content | | Temperature |
| Division | (weight %) | Type | (weight %) | Water | (° C.) |
| Inventive | 85 | A-1 | 1 | Remaining Amount | 160 |
| Example 1 | | | | | |
| Inventive | 85 | A-2 | 1 | Remaining Amount | 160 |
| Example 2 | | | | | |
| Inventive | 85 | A-3 | 1 | Remaining Amount | 160 |
| Example 3 | | | | | |
| Inventive | 85 | A-4 | 1 | Remaining Amount | 160 |
| Example 4 | | | | | |
| Inventive | 85 | A-5 | 1 | Remaining Amount | 160 |
| Example 5 | | | | | |
| Inventive | 85 | A-6 | 1 | Remaining Amount | 160 |
| Example 6 | | | | | |
| Inventive | 85 | A-7 | 1 | Remaining Amount | 160 |
| Example 7 | | | | | |
| Inventive | 85 | A-8 | 1 | Remaining Amount | 160 |
| Example 8 | | | | | |
| Inventive | 85 | A-9 | 1 | Remaining Amount | 160 |
| Example 9 | | | | | |
| Inventive | 85 | A-10 | 1 | Remaining Amount | 160 |
| Example 10 | | | | | |
| Comparative | 85 | — | — | Remaining Amount | 160 |
| Example 1 | | | | | |
| Comparative | 85 | B-1 | 1 | Remaining Amount | 160 |
| Example 2 | | | | | |
| Comparative | 85 | B-2 | 1 | Remaining Amount | 160 |
| Example 3 | | | | | |

A-1: R₁ = Aminopropyl; R₄ = Hydroxymethyl; R₂, R₃, R₅, R₆ = Hydroxy
A-2: R₁ = Aminopropyl; R₄ = Hydroxymethyl; R₂, R₃, R₅, R₆ = phosphate
A-3: R₁ = N-(2-Aminoethyl)-3-aminopropyl; R₄ = Hydroxymethyl; R₂, R₃, R₅, R₆ = Hydroxy
A-4: R₁ = N-(2-Aminoethyl)-3-aminopropyl; R₄ = Hydroxymethyl; R₂, R₃, R₅, R₆ = phosphate
A-5: R₁ = N-(2-Aminoethyl)-3-aminopropyl; R₄ = Chloromethyl; R₂, R₃, R₅, R₆ = Hydroxy
A-6: R₁ = N-(2-Aminoethyl)-3-aminopropyl; R₄ = Chloromethyl; R₂, R₃, R₅, R₆ = phosphate
A-7: R₁ = Aminopropyl; R₄ = Hydroxymethyl; R₂, R₃, R₅ = Hydroxy; R₆ = methyl
A-8: R₁ = Aminopropyl; R₄ = Hydroxymethyl; R₂, R₃, R₅ = Phosphate; R₆ = methyl
A-9: R₁ = Aminopropyl ; R₄ = methyl; R₂, R₃, R₅, R₆ = Hydroxy
A-10: R₁ = Aminopropyl; R₄ = methyl; R₂, R₃, R₅, R₆ = phosphate
B-1: Methyl triethoxysilane
B-2: Aminopropyl triethoxysilane

TABLE 2

| | | | | Bubble |
|---|---|---|---|---|
| | Etching Rate (Å/min) | | | Generation |
| | Nitride Layer | Oxide Layer | Selectivity | Height (cm) |
| Inventive | 64.4 | 0.05 | 1288 | 2.0 |
| Example 1 | | | | |
| Inventive | 64.2 | 0.04 | 1605 | 2.1 |
| Example 2 | | | | |
| Inventive | 63.5 | 0.06 | 1058 | 2.8 |
| Example 3 | | | | |
| Inventive | 63.2 | 0.04 | 1580 | 2.7 |
| Example 4 | | | | |
| Inventive | 65.1 | 0.06 | 1085 | 3.3 |
| Example 5 | | | | |
| Inventive | 64.9 | 0.05 | 1298 | 3.5 |
| Example 6 | | | | |
| Inventive | 64.8 | 0.03 | 2160 | 3.1 |
| Example 7 | | | | |
| Inventive | 65.2 | 0.04 | 1630 | 2.9 |
| Example 8 | | | | |
| Inventive | 63.3 | 0.06 | 1055 | 5.3 |
| Example 9 | | | | |
| Inventive | 63.2 | 0.05 | 1264 | 5.2 |
| Example 10 | | | | |
| Comparative | 71.2 | 3.30 | 22 | 1.0 |
| Example 1 | | | | |
| Comparative | 65.1 | 0.17 | 383 | 18.1 |
| Example 2 | | | | |
| Comparative | 65.4 | 0.87 | 75 | 13.4 |
| Example 3 | | | | |

TABLE 3

| | Si concentration | Abnormal Growth | Precipitate |
|---|---|---|---|
| | of Etching | of Oxide Layer | Occurrence |
| | Byproducts (ppm) | (Å) | (O/X) |
| Inventive | 100 | 0.0 | X |
| Example 1 | 200 | 0.0 | X |
| | 300 | 0.0 | X |
| Inventive | 100 | 0.0 | X |
| Example 2 | 200 | 0.0 | X |
| | 300 | 0.0 | X |
| Inventive | 100 | 0.0 | X |
| Example 3 | 200 | 0.0 | X |
| | 300 | 0.0 | X |
| Inventive | 100 | 0.0 | X |
| Example 4 | 200 | 0.0 | X |
| | 300 | 0.0 | X |
| Inventive | 100 | 0.0 | X |
| Example 5 | 200 | 0.0 | X |
| | 300 | 0.6 | X |
| Inventive | 100 | 0.0 | X |
| Example 6 | 200 | 0.0 | X |
| | 300 | 0.5 | X |
| Inventive | 100 | 0.0 | X |
| Example 7 | 200 | 0.0 | X |
| | 300 | 0.0 | X |
| Inventive | 100 | 0.0 | X |
| Example 8 | 200 | 0.0 | X |
| | 300 | 0.0 | X |
| Inventive | 100 | 0.0 | X |
| Example 9 | 200 | 0.0 | X |
| | 300 | 1.4 | X |
| Inventive | 100 | 0.0 | X |
| Example 10 | 200 | 0.0 | X |
| | 300 | 1.3 | X |
| Comparative | 100 | 12.3 | X |
| Example 1 | 200 | 33.4 | O |
| | 300 | 61.8 | O |
| Comparative | 100 | 5.9 | X |
| Example 2 | 200 | 48.3 | O |
| | 300 | 85.6 | O |
| Comparative | 100 | 4.7 | X |
| Example 3 | 200 | 34.3 | X |
| | 300 | 61.1 | O |

As may be seen in Table 2 above, it may be confirmed that the etching compositions of the inventive examples have significantly superior etching selectivity to those of the comparative examples, and it may be confirmed that the height of bubbles is properly kept low. Specifically, the etching composition including a compound in which R₁ has aminoalkyl as a substituent and R₄ has hydroxyalkyl or chloroalkyl as a substituent was shown to have a lower bubble generation height than that of the etching composition including a compound in which R₄ is alkyl.

Meanwhile, referring to Table 3, it may be confirmed that the etching compositions of the inventive examples suppress abnormal growth of the oxide layer better than those of the comparative examples and that no precipitates are generated. Specifically, the etching composition including a compound in which R₁ has aminoalkyl as a substituent and R₄ has hydroxyalkyl as a substituent was shown to have significantly suppressed abnormal growth even in a solution having a high Si concentration of the etching byproducts.

As described above, the present disclosure has been described with specific matters and limited embodiments and drawings, but this is provided to help a general understanding of the present disclosure, and the present invention is not limited to the aforementioned embodiments, and a person skilled in the art to which the present disclosure pertains may make various changes and modifications.

What is claimed is:

1. An etching composition for a silicon nitride layer, comprising:
phosphoric acid, a silicon-based compound represented by Formula 1, and water,
(R₁R₂R₃)Si—O—Si(R₄R₅R₆) [Formula 1]
(where R₁ is *-L₁-[N(R₇)-L₂]ₙ-N(R₈R₉),
R₄ is selected from (C1-C7)alkyl, hydroxy (C1-C7)alkyl, (C1-C7)alkylamino, hydroxy (C1-C7)alkylamino, (C1-C7)alkoxy, hydroxy (C1-C7)alkoxy, and chloro (C1-C7)alkyl,
R₂, R₃, R₅ and R₆ are each independently selected from halogen, hydroxy, (C1-C7)alkyl, (C1-C7)alkoxy, (C1-C7)alkylamino, chloro (C1-C7)alkyl, and *-O—P(═O)(OR₁₀) (OR₁₁),
L₁ and L₂ are each independently (C1-C10)alkylene,
R₇ to Run are each independently hydrogen or (C1-C7)alkyl,
n is an integer from 0 to 10, and
at least one —CH₂— of (C1-C10)alkylene of L₁ and L₂ may be substituted with —O—, —OC(═O)—, —NHC(═O)—, —NHC(═O)O—, —C(═O)—or— OC(═O)O—).

2. The etching composition for a silicon nitride layer according to claim 1,
wherein in Formula 1,
R₄ is selected from hydroxy(C1-C7)alkyl, hydroxy(C1-C7)alkoxy, and hydroxy(C1-C7)alkylamino.

3. The etching composition for a silicon nitride layer according to claim 2,
wherein in Formula 1,
R₄ is hydroxy(C1-C7)alkyl.

4. The etching composition for a silicon nitride layer according to claim 1,
wherein in Formula 1,
R₂, R₃, R₅ and R₆ are each independently selected from hydroxy, (C1-C7)alkyl, (C1-C7)alkoxy, and *-O—P(═O)(OR₁₀)(OR₁₁).

5. The etching composition for a silicon nitride layer according to claim 4,
wherein in Formula 1,
R₂, R₃, R₅ and R₆ are each independently selected from hydroxy, (C1-C4)alkoxy, and *-O—P(═O)(OR₁₀)(OR₁₁).

6. The etching composition for a silicon nitride layer according to claim 1,
wherein in Formula 1,
L₁ and L₂ are independently be (C1-C4)alkylene, R₇ to R₉ are independently hydrogen or (C1-C4)alkyl, and n is an integer of 0 to 5.

7. The etching composition for a silicon nitride layer according to claim 6,
wherein in Formula 1,
L₁ and L₂ are each independently (C1-C4)alkylene, R₇ to R₉ are hydrogen, and n is an integer from 0 to 3.

8. The etching composition for a silicon nitride layer according to claim 1,
wherein a compound represented by formula 1 is selected from the following compounds:
(OH)₂(R₁ₐ)Si—O—Si(R₄ₐ) (OH)₂ [Formula 2]
(—O—P(═O)(OH)₂)₂(R₁ₐ)Si—O—Si(R₄ₐ)(—O—P(═O)(OH)₂)₂ [Formula 3]
(OH)(R₁ₐ)(R₂ₐ)Si—O—Si(R₄ₐ)(OH)₂ [Formula 4]
(—O—P(═O)(OH)₂)(R₁ₐ)(R₂ₐ)Si—O—Si(R₄ₐ)(—O—P(═O)(OH)₂)₂ [Formula 5]
where R₁ₐ is *-(CH₂)ₘ—NH₂ or *-(CH₂)₃—[NH—(CH₂)₂]—NH₂, R₂ₐ is methyl or ethyl, R₄ₐ is hydroxy(C1-C2)alkyl or chloro(C1-C2)alkyl, and m is an integer of 2 to 4.

9. The etching composition for a silicon nitride layer according to claim 1,
wherein a compound represented by formula 1 is selected from the following compounds:
(OH)₂(R_{1b})Si—O—Si(R_{4b}) (OH)₂ [Formula 6]
(—O—P(═O)(OH)₂)₂(R_{1b})Si—O—Si(R_{4b})(—O—P(═O)(OH)₂)₂ [Formula 7]
(OH) (R_{1b})(R_{2b})Si—O—Si(R_{4b})(OH)₂ [Formula 8]
(—O—P(═O)(OH)₂)(R_{1b})(R_{2b})Si—O—Si(R_{4b})(—O—P(═O)(OH)₂)₂ [Formula 9]
where R_{1b} is *-(CH₂)ₘ—NH₂ or *-(CH₂)₃—[NH—(CH₂)₂]—NH₂, R_{2b} is methyl or ethyl, and R_{4b} is (C1-C2)alkyl.

10. The etching composition for a silicon nitride layer according to claim 1,
wherein the etching composition includes 80 to 90 wt % of phosphoric acid, 0.01 to 10 wt % of a silicon-based compound represented by Formula 1, and a residual amount of water.

11. The etching composition for a silicon nitride layer according to claim 1, further comprising:
one or two or more combinations selected from the group consisting of pyrophosphoric acid, polyphosphoric acid, phosphorous acid, dialkyl phosphite, sulfuric acid, alkylsulfonic acid, hydrochloric acid, hydrofluoric acid, and derivatives thereof.

12. The etching composition for a silicon nitride layer according to claim 1, further comprising:
an ammonium-based compound.

13. The etching composition for a silicon nitride layer according to claim 1,
wherein etching selectivity of the following relational expression 1 is satisfied,
500≤E_{SiNx}/E_{SiO2} [Relational Expression 1]
where E_{SiNx}is an etching rate of the silicon nitride layer, and E_{SiO2} is an etching rate of the silicon oxide layer.

14. A method of manufacturing a semiconductor device including an etching process using the composition for etching a silicon nitride layer selected in claims 1.
